(19) United States
(12) Patent Application Publication
(10) Pub. No.: US 2008/0237660 A1
(43) Pub. Date: Oct. 2, 2008

(54) METHOD TO DEPOSIT SILICON FILM ON A SUBSTRATE

(76) Inventors: Ajay K. Sharma, Beaverton, OR (US); Anand Murthy, Portland, OR (US); Din-How Mei, Beaverton, OR (US); Dennis Hanken, Beaverton, OR (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/693,903

(22) Filed: Mar. 30, 2007

(51) Int. Cl. H01L 29/94; C30B 19/00

(52) U.S. Cl. 257/288; 117/58; 257/E29.345

(57) ABSTRACT

A semiconductor device and a method to fabricate a semiconductor device on a silicon substrate are illustrated. The semiconductor may comprise an amorphous silicon film, in the source/drain region of a semiconductor, having low amount of hydrogen and high concentration of carbon and phosphorous, which enhances performance of the semiconductor device.

### BACKGROUND

A thin film of a material, such as silicon (Si), may be fabricated in the source/drain (S/D) region of a substrate to fabricate semiconductors devices, such as, transistors. The thin film may be fabricated in various forms, for example, amorphous, epitaxial, monocrystalline and polycrystalline. The substrate may comprise a bare Si substrate and an oxide Si substrate. The transistors may, for example, comprise an N-channel metal oxide semiconductor (NMOS) transistor and a P-channel metal oxide semiconductor (PMOS) transistor. However, the thin film fabrication process may not be controlled to get the film of the required thickness and quality to have sufficient carrier mobility and reducing spreading resistance in the transistors.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 illustrates a cross-sectional view of a strained NMOS transistor.

FIG. 2 illustrates an embodiment of a process of the present invention that may be implemented to fabricate silicon film in the S/D region of a substrate to fabricate the transistor of FIG. 1.

FIGS. 3A-3B illustrates amorphous silicon film deposition thickness test results at different levels of silane flow.

FIGS. 4A-4B illustrates an amount of hydrogen presence in the amorphous silicon film deposited on different substrates at different levels of silane flow.

FIGS. 5A-5B illustrates amorphous silicon film deposition thickness against a hydrogen to silane flow ratio.

### DETAILED DESCRIPTION

In the following detailed description, numerous specific details are described in order to provide a thorough understanding of the invention. However the present invention may be practiced without these specific details. In other instances, well known methods, procedures, components and circuits have not been described in detail so as not to obscure the present invention. Further, exemplary sizes, values and ranges may be given, but it should not be understood that the present invention is limited to these specific example.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

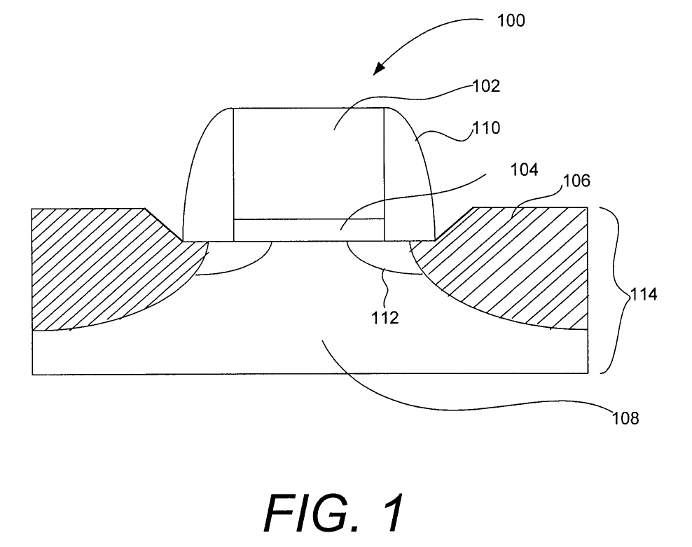

Referring to FIG. 1, a sectional view of an N-channel metal oxide semiconductor (NMOS) transistor 100 is illustrated. The transistor 100 may comprise a gate electrode 102 mounted on a gate dielectric layer 104. The gate dielectric layer 104 may be mounted on a channel region 106 of a substrate 108. The gate dielectric layer 104 and gate electrode 102 may be isolated by gate isolation spacers 110. Tip extensions 112 may be formed by implanting dopant atoms, such as a charge carrier dopant impurity atom, into substrate 108. The dopant may, for example, comprise phosphorous, carbon, arsenic or any combination.

In one embodiment, uniaxially strained source/drain (S/D) regions 114 may be formed by selectively growing an epitaxial film in etched-out portions of the substrate 108. The uniaxially strained S/D region 114 may be doped either in situ or after epitaxial film growth, or both. In one embodiment, the uniaxially strained S/D region 114 may comprise carbon (C) and phosphorous (P) which may be needed to achieve appreciable tensile strain in the channel region 108 and to minimize parasitic spreading resistance in the S/D region 106. In one embodiment, the uniaxial tensile strain in the channel region 108 may enhance hole mobility in the channel region 106 to improve the performance of the semiconductor device.

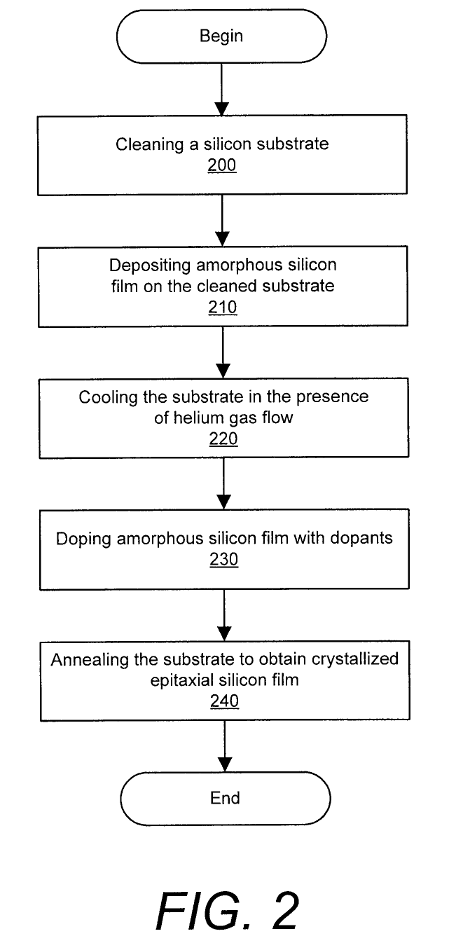

Reference is now made to FIG. 2, an embodiment of a process to selectively deposit a silicon film in the S/D region 114 of a substrate 108 is illustrated. The process, as shown in block 200, may comprise pre-treating a substrate 108 with hydrogen plasma to clean the substrate 108. The hydrogen plasma pretreatment (PT) may be carried out at a hydrogen flow rate of about 9,000 to about 18,000 standard cubic centimeters per minute (SCCM), for a period of about 30 to about 200 seconds, at a pressure of about 2 to about 8 Torr and at a temperature of about 500 to about 600 ⁰C. The high frequency radio frequency (HFRF) power and the low frequency radio frequency (LFRF) power during the process of hydrogen plasma pre-treatment may be maintained in the range of 200-1000 watts and 400-1000 watts, respectively.

In one embodiment, the hydrogen plasma pre-treatment may be carried on at the flow of hydrogen in the range of about 9,300 to about 9,700 SCCM, for about 35 to about 85 seconds and at a pressure of about 2 to about 3 Torr. The substrate may, for example, comprise a virgin test (VT) silicon (Si) substrate. The hydrogen, in one embodiment, may be produced by exposing the surface of the VT Si substrate 108 to hydrogen plasma.

As shown in block 210, a film of silicon, such as, amorphous silicon (a-Si) may be deposited on source/drain (S/D) region 114 of the Si substrate 108 at a temperature in the range of about 500 to about 600 ⁰C for a period of about 10 to about 60 second, at a pressure of about 1.5 to about 8 Torr and in the presence of a flow of hydrogen (H₂) in the range of about 1,000 to about 18,000 SCCM and a flow of silane (SiH₄) at about 100 to about 1400 SCCM. The high frequency radio frequency (HFRF) power and the low frequency radio frequency (LFRF) power, during the process of amorphous Si film deposition, may be maintained at about 200 to about 1,000 watts and about 400 to about 1,500 watts, respectively.

In one embodiment, the deposition of the amorphous silicon film may be carried on at the high temperature so as to select low amount of hydrogen content in the a-Si film. In one embodiment, the hydrogen content present in the a-Si film may be less than 2 atomic percent. In one embodiment, the ratio of H₂ and SiH₄ may be selected to achieve complete or partial deposition of the amorphous silicon film, selectively, on the substrate. The flow of silane may be maintained at about 100 to about 1400 SCCM to select thickness of the a-Si film. In one embodiment, the silane may be maintained at about 200 to about 800 SCCM.

In one embodiment, the a-Si film deposition process may be carried on at a temperature of about 500 to about 550 ⁰C, for about 40 to about 60 seconds, at a pressure of about 2 to about 4 Torr, and in with a flow of hydrogen of about 1,000 to about 9,000 SCCM. In one embodiment, the a-Si film may be deposited using a plasma enhanced chemical vapor deposition (PECVD) apparatus.

As shown in block 220, the substrate having the a-Si film deposited thereon may be cooled. In one embodiment, the substrate may be cooled in Loadlock chamber of PECVD in presence of an inert gas, such as, helium (He) gas.

As shown in block 230, the a-Si film may be doped with dopants, for example, carbon (C) and phosphorous (P). In one embodiment, the S/D region of the semiconductor device may be doped. The amount of the dopants, in one embodiment, may be selected by controlling dose and energy of the dopants. In one embodiment, the amount of C contained in the a-Si film may be greater than 2 percent and the amount of P contained may be greater than 5E20 atoms/cm³. In one embodiment, the dopants may be required to achieve appreciable uniaxial tensile strain in the channel region 108 of the semiconductor device which may enhance hole mobility in the channel region 106 and improve the performance of the semiconductor device.

As shown in block 240, the substrate having the amorphous silicon film deposited thereon along with the dopants may be subjected to annealing, for example, transient annealing. The annealing may be performed to transform amorphous Si film to epitaxial Si film. In one embodiment, annealing may be performed by heating the substrate to crystallize the a-Si film and activate dopant forming contacts in the S/D regions by transforming the a-Si film into a uniaxially tensile strained epitiaxial silicon film.

In one embodiment, the amorphous silicon film may also be deposited on virgin test silicon substrate by using same process as described herein above to deposit the a-Si film on the oxide substrate. The VT Si substrate and the oxide substrate, having amorphous Si film deposited thereon may also be tested to the thickness of the a-Si film and to determine amount of the H₂ present in the a-Si film.

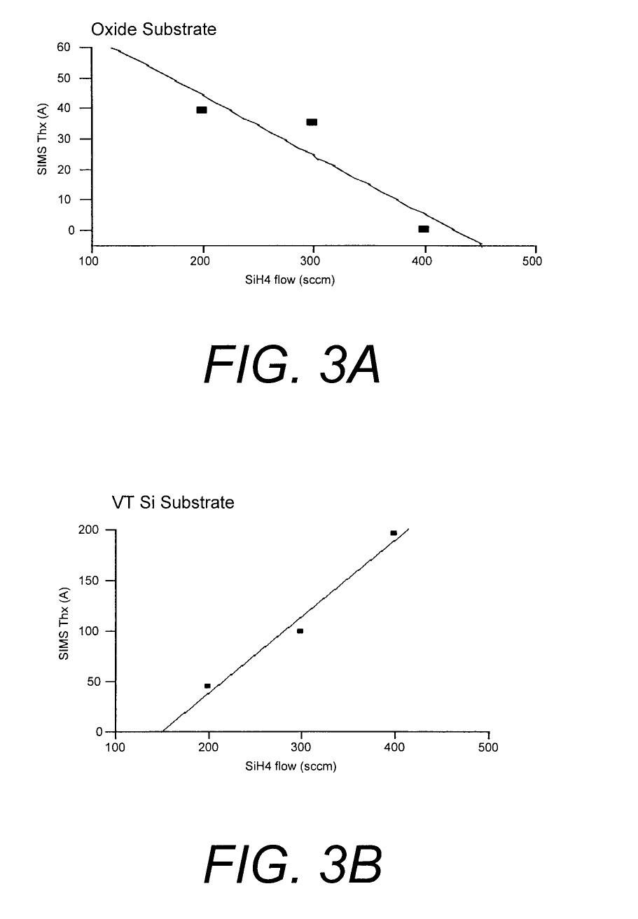

Referring to FIG. 3A, test results of the a-Si film deposition at different flow rates of silane are illustrated. In one embodiment, the VT Si substrate and the oxide Si substrate were tested by secondary ion mass spectrometry (SIMS) test process to detect deposition of amorphous Si film at different flow of SiH₄ in the range of 200-500 SCCM. The a-Si film deposition is reduced upon increasing the flow of SiH₄ and the deposition may be low or zero on the oxide substrate at 400 or higher SCCM of SiH₄ flow. However, as shown in FIG. 3B, the a-Si film deposition increases upon increase of the flow of SiH₄ and the deposition may be higher on the VT Si substrate at 400 SCCM silane flow. Thus, the deposition of the a-Si film on the oxide substrate may be selected by flowing controlled amount of silane during the deposition of a-Si film on the Oxide substrates.

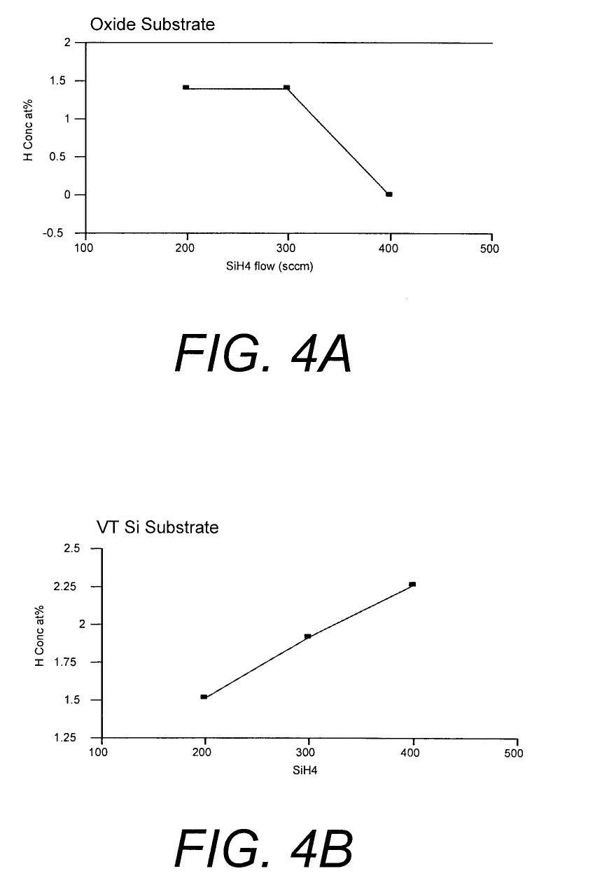

Referring to FIG. 4A, test results of the amount of H2 present in the a-Si film at different flow rates of silane are illustrated. In one embodiment, the VT Si substrate and the oxide substrate were tested by using a secondary ion mass spectrometry (SIMS) test process to detect the amount H₂ at different flow of silane in the range of 200-500 SCCM. It may be observed that the amount of H₂ present in the a-Si film reduces upon increasing the flow of SiH₄ and deposition may be low on the oxide substrate at 400 SCCM SiH₄ flow rate.

However, as shown in FIG. 4B, the amount of H₂ present in the a-Si—H film increases upon increasing the flow of SiH₄ and may be higher on the VT Si substrate at 400 SCCM SiH4 flow rate. Thus, the amount of H₂ present in the a-Si—H film on the oxide substrate may be selected by flowing controlled amount of SiH₄ during the deposition of a-Si film on the Oxide substrate and VT Si substrate.

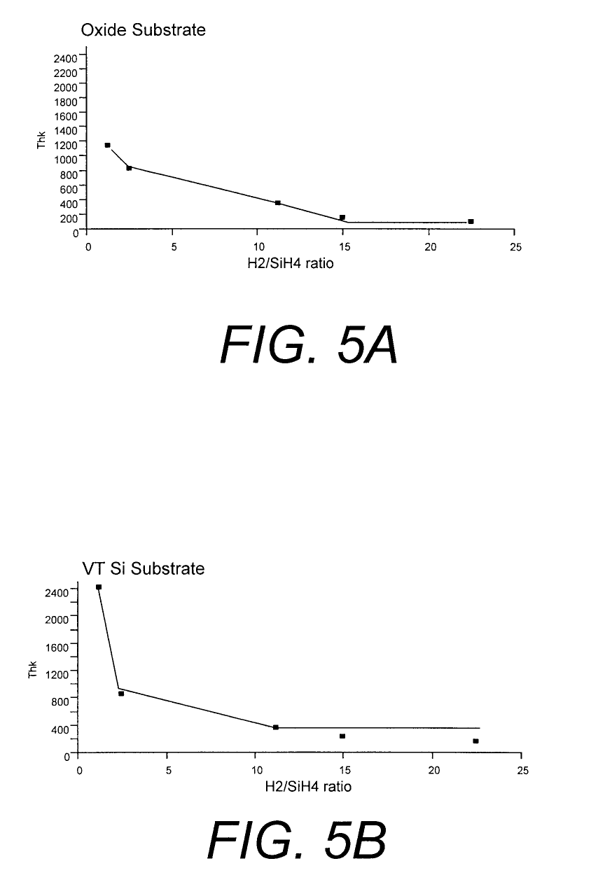

Referring to FIGS. 5A and 5B, test results of etching effect on substrate during the a-Si film deposition at different H₂/SiH₄ ratio are illustrated. In one embodiment, the VT Si substrate and the oxide Si substrate were tested to detect deposition of amorphous Si film at different ratio of H₂/SiH₄ in the range of about 1 to about 50. The a-Si film deposition is reduced upon increasing the H₂/SiH₄ ratio and the deposition may be low or zero on the oxide substrate and VT Si substrates.

Certain features of the invention have been described with reference to example embodiments. However, the description is not intended to be construed in a limiting sense. Various modifications of the example embodiments, as well as other embodiments of the invention, which are apparent to persons skilled in the art to which the invention pertains are deemed to lie within the spirit and scope of the invention.

What is claimed is:

1. A method to form an epitaxial silicon film on a silicon substrate, comprising:
cleaning the silicon substrate;
depositing a film of amorphous silicon on the silicon substrate;
heating the amorphous silicon film to about 500 to about 600 ⁰C to select hydrogen content in the amorphous silicon film;
cooling the substrate and the amorphous silicon film; and
annealing the substrate to form the epitaxial silicon film.

2. The method of claim 1, further comprising doping the amorphous silicon film.

3. The method of claim 1, wherein the cleaning comprises disposing hydrogen plasma at a flow rate of about 9,000 to about 18,000 standard cubic centimeters per minute.

4. The method of claim 3, wherein the cleaning comprises disposing hydrogen plasma at a flow rate of about 9,300 to about 9,700 standard cubic centimeters per minute.

5. The method of claim 1, wherein the film of amorphous silicon is deposited on the source/drain region of the silicon substrate at a pressure of about 1.5 to about 8 Torr.

6. The method of claim 5, wherein the film of amorphous silicon is deposited on the silicon substrate at a temperature in the range of 500-550 ⁰C and at a pressure of about 2 to about 4 Torr.

7. The method of claim 6, wherein the film of amorphous silicon is deposited at a high frequency RF from about 200 watts to about 1,000 watts and a low frequency RF from about 400 watts to about 1500 watts.

8. The method of claim 1, wherein the film of amorphous silicon is deposited using a plasma enhanced chemical vapor deposition apparatus.

9. The method of claim 8, wherein the film of amorphous silicon is deposited in a presence of silane.

10. The method of claim 9, wherein the film of amorphous silicon is deposited in a presence of hydrogen and silane.

11. A semiconductor device, comprising;
a gate electrode mounted on a dielectric layer, wherein the dielectric layer is mounted on a channel region of a silicon substrate;
a source/drain region provided on both sides of the channel region; and
an amorphous silicon film provided on the source/drain region of the silicon substrate, wherein the amorphous silicon film has a low amount of hydrogen less than 2 atomic percent.

12. The semiconductor device of claim 11, wherein the amorphous silicon film is deposited through plasma enhanced chemical vapor deposition at a temperature of about 500° C. to about 600° C.

13. The semiconductor device of claim 12, wherein the film of amorphous silicon is deposited at a pressure from about 2 Torr to about 4 Torr.

14. The method of claim 13, wherein the film of amorphous silicon is deposited in a presence of silane.
